(19) United States
(12) Patent Application Publication
(10) Pub. No.: US 2026/0035800 A1
(43) Pub. Date: Feb. 5, 2026

(54) SELF-FILLING METHOD FOR HIGH-ASPECT-RATIO MICROVIAS IN SUBSTRATE

(71) Applicant: Guangdong University of Technology, Guangzhou (CN)

(72) Inventors: Yu ZHANG, Guangzhou (CN); Yutao LI, Guangzhou (CN); Weizhong HUANG, Guangzhou (CN); Guannan YANG, Guangzhou (CN); Guanghan HUANG, Guangzhou (CN); Chengqiang CUI, Guangzhou (CN)

(21) Appl. No.: 19/356,158

(22) Filed: Oct. 12, 2025

(30) Foreign Application Priority Data
Jan. 15, 2025 (CN) 202510059698.2

(51) Int. Cl. C23C 24/10; C03C 17/00; C03C 17/06; H01L 21/768

(52) U.S. Cl. CPC C23C 24/103; C03C 17/007; C03C 17/06; H01L 21/76882; C03C 2217/253; C03C 2218/114; C03C 2218/32

(57) ABSTRACT

A self-filling method for high-aspect-ratio microvias of a substrate is provided, in which the substrate is activated with a coupling agent; a pasty nano-filler is applied onto a surface of the substrate, where the microvias in the substrate are self-filled with the pasty nano-filler through capillary action, the pasty nano-filler has a wetting angle of α≤30°, and each of the microvias has an aspect ratio of 5-500:1 and a diameter of 1-100 μm; and the coated substrate is subjected to sintering treatment.

### CROSS-REFERENCE TO RELATED APPLICATIONS

This application claims the benefit of priority from Chinese Patent Application No. 202510059698.2, filed on Jan. 15, 2025. The content of the aforementioned application, including any intervening amendments made thereto, is incorporated herein by reference in its entirety.

### TECHNICAL FIELD

This application relates to packaging of semiconductor power devices, and more particularly to a self-filling method for high-aspect-ratio microvias in a substrate.

### BACKGROUND

Microvia filling technology, as one of the critical technologies in the integrated circuit manufacturing, enables the interlayer interconnection. It has been widely adopted in the fabrication of printed circuit boards (PCBs) and integrated circuits, demonstrating brilliant application prospects in the advanced packaging, micro-electro-mechanical systems (MEMS) and silicon photonics.

For high-aspect-ratio holes, conventional via-filling processes rely on external equipment (such as vacuum or pressure assistance), resulting in complex process and high cost. For example, Japanese patent publication No. 2011091117A discloses a method of filling interlayer through-holes with powder, in which a pressure fixture is used to apply pressure to the filled powder. Existing via-filling technologies are categorized into conductive metal paste filling and direct electroplating filling. Chinese patent publication No. 119095286A discloses a via-filling method for glass substrates using conductive copper paste, in which copper atoms are deposited onto a copper seed layer by using a copper electroplating process to increase a thickness of the copper seed layer on a surface of the glass substrate and an inner wall of vias. A vacuum plugging process is used to fill the vias with a conductive copper paste. However, this vacuum plugging approach is costly, and can only achieve a stable yield when filling vias with a diameter of 100-250 μm, failing to meet the fabrication requirements of fine circuits. Chinese patent publication No. 115460798A discloses a via-filling method for a ceramic substrate, in which a conductive layer is deposited on a surface of the ceramic substrate by vacuum sputtering to form a seed layer. Laser-drilled vias in the ceramic substrate are processed by pulse electroplating to form interconnected copper layers. However, this electroplating filling technique will easily lead to the occurrence of bubbles or voids in the copper layers, thereby severely affecting the yield of the substrate and the service life of power devices.

### SUMMARY

An object of the present disclosure is to provide a self-filling method for high-aspect-ratio microvias of a substrate, which enables the simple and reliable filling of high-aspect-ratio microvias on the substrate with low cost.

Technical solutions of the present disclosure are described as follows.

A self-filling method for high-aspect-ratio microvias of a substrate, comprising:
(1) activating the substrate with a coupling agent to obtain an activated substrate;
(2) applying a pasty nano-filler on a surface of the activated substrate; wherein microvias in the activated substrate are self-filled with the pasty nano-filler through capillary action, the pasty nano-filler has a wetting angle of α≤30°, and each of the microvias has an aspect ratio of 5-500:1 and a diameter of 1-100 μm; and
(3) subjecting a nano-filler-coated substrate obtained in step (2) to sintering treatment.

In some embodiments, when the diameter of each of the microvias is 1-10 μm, the wetting angle of the pasty nano-filler is α≤15°;
when the diameter of each of the microvias is 10-50 μm, the wetting angle of the pasty nano-filler is α≤20°; and
when the diameter of each of the microvias is 50-100 μm, the wetting angle of the pasty nano-filler is α≤30°.

In some embodiments, the pasty nano-filler comprises an interfacial modifier; and the interfacial modifier is selected from the group consisting of an amine compound, a C₁-C₆ alcohol, a C₂-C₆ ether and an organic acid.

In some embodiments, the interfacial modifier is selected from the group consisting of diethylamine, triethylamine, octylamine, ethanol, butanol, diethylene glycol monomethyl ether, formic acid, acetic acid and citric acid.

In some embodiments, the pasty nano-filler has a viscosity of 1-10 Pa·s; and the pasty nano-filler further comprises metal particles having a particle size of 10-100 nm.

In some embodiments, step (1) comprises:
immersing the substrate in an acid solution followed by washing and drying to obtain a pre-treated substrate; and
immersing the pre-treated substrate in an ethanol solution of the coupling agent followed by washing and drying to obtain the activated substrate.

In some embodiments, the substrate is an organic substrate; and before immersed in the ethanol solution of the coupling agent, the pre-treated substrate is subjected to plasma treatment.

In some embodiments, the substrate is a glass substrate, a ceramic substrate, an organic substrate or a metal substrate; and the coupling agent is a silane coupling agent or a titanate coupling agent.

In some embodiments, in step (2), the pasty nano-filler is applied onto the surface of the activated substrate by blade coating to reach a thickness of 10-30 μm, and the nano-filler-coated substrate is left to stand at room temperature, during which the microvias are self-filled with the pasty nano-filler through the capillary action.

In some embodiments, in step (3), the sintering treatment is performed through steps of:
heating the nano-filler-coated substrate to 200-400° C. in a protective atmosphere at a rate of 10-20° C./min, and sintering the nano-filler-coated substrate at 200-400° C. for 5-30 min followed by cooling to room temperature at a rate of 5-10° C./min.

Compared to the prior art, the present disclosure has the following beneficial effects.

In the present disclosure, the substrate is activated with the coupling agent to enhance an interfacial bonding force on the surface of the substrate and on inner walls of the microvias, thereby improving wettability. Based on the pasty nano-filler having the wetting angle of α≤30°, high-aspect-ratio microvias can be filled through wettability regulation and capillary action, achieving excellent filling performance for microvias with a diameter of 1-100 μm and an aspect ratio of 5-500:1. The method provided herein enables self-filling of high-aspect-ratio microvias of the substrate under the driving force of capillary action without the need for external pressure or vacuum assistance, and is characterized by simple and efficient operation steps, low cost, and reliable filling performance for small and high-aspect-ratio microvias.

### DETAILED DESCRIPTION OF EMBODIMENTS

An embodiment of the present disclosure provides a self-filling method for high-aspect-ratio microvias of a substrate, which is used for reliably filling small and high-aspect-ratio microvias on the substrate to achieve interlayer circuit connection.

The method includes the following steps.

(1) The substrate is activated with a coupling agent to obtain an activated substrate.

(2) A pasty nano-filler is applied on a surface of the activated substrate, where microvias in the activated substrate are self-filled with the pasty nano-filler through capillary action, the pasty nano-filler has a wetting angle of α≤30°, and each of the microvias has an aspect ratio of 5-500:1 and a diameter of 1-100 μm.

(3) A nano-filler-coated substrate obtained in step (2) is subjected to sintering treatment.

In the present disclosure, the substrate is activated with the coupling agent to enhance an interfacial bonding force on the surface of the substrate and on inner walls of the microvias, thereby improving wettability. Based on the pasty nano-filler having the wetting angle of α≤30°, high-aspect-ratio microvias can be filled through wettability regulation and capillary action, achieving excellent filling performance for microvias with a diameter of 1-100 μm and an aspect ratio of 5-500:1. The method provided herein enables self-filling of high-aspect-ratio microvias of the substrate under the driving force of capillary action without the need for external pressure or vacuum assistance, and is characterized by simple and efficient operation steps, low cost, and reliable filling performance for small and high-aspect-ratio microvias. The pasty nano-filler is selected from the group consisting of a nano-silver paste, a nano-copper paste, a carbon nanotube paste and a graphene paste. In some embodiments, the pasty nano-filler is the nano-copper paste.

In some embodiments, when the diameter of each of the microvias is 1-10 μm, the wetting angle of the pasty nano-filler is α≤15°. When the diameter of each of the microvias is 10-50 μm, the wetting angle of the pasty nano-filler is α≤20°. When the diameter of each of the microvias is 50-100 μm, the wetting angle of the pasty nano-filler is α≤30°.

Based on different diameters of the microvias, the wetting angle of the pasty nano-filler is set to ensure that the microvias can be filled within a shorter time. When the diameter becomes smaller, a smaller wetting angle of the pasty nano-filler is required, such that the microvias are filled under the capillary driving force, thereby ensuring a reliable filling effect of the microvias.

In order to reduce the wetting angle of the pasty nano-filler, in some embodiments, the pasty nano-filler includes an interfacial modifier. The interfacial modifier is selected from the group consisting of an amine compound, a C₁-C₆ alcohol, a C₂-C₆ ether and an organic acid.

The addition of the amine compound, the low-molecular-weight alcohol, the low-molecular-weight ether and the organic acid can reduce the wetting angle of the pasty nano-filler, allowing its surface tension to be lower than 30 mN/m. The interfacial modifier is used to reduce aggregation among metal particles and interacts with the metal particles to enhance the flowability of the pasty nano-filler, such that the high-aspect-ratio microvias are fully filled with the pasty nano-filler.

In some embodiments, the interfacial modifier is selected from the group consisting of diethylamine, triethylamine, octylamine, ethanol, butanol, diethylene glycol monomethyl ether, formic acid, acetic acid and citric acid.

Based on the wetting angle requirements of the pasty nano-filler for microvias with different diameters, a weight percentage concentration of the interfacial modifier in the pasty nano-filler is 0.1-3%. In some embodiments, for microvias having a diameter of 1-10 μm, the weight percentage concentration of the interfacial modifier in the pasty nano-filler is 2-3%; for microvias having a diameter of 10-50 μm, the weight percentage concentration of the interfacial modifier in the pasty nano-filler is 1-2%; and for microvias having a diameter of 50-100 μm, the weight percentage concentration of the interfacial modifier in the pasty nano-filler is 0.1-1%.

In order to further improve the filling performance, the pasty nano-filler has a viscosity of 1-10 Pa·s, and the pasty nano-filler further includes metal particles having a particle size of 10-100 nm. In some embodiments, the pasty nano-filler may have viscosities of 1 Pa·s, 3 Pa·s, 5 Pa·s, 8 Pa·s or 10 Pa·s, and the metal particles have particle sizes of 10 nm, 30 nm, 80 nm or 100 nm.

In some embodiments, step (1) includes the following steps. The substrate is immersed in an acid solution, washed and dried to obtain a pre-treated substrate. The pre-treated substrate is immersed in an ethanol solution of the coupling agent, washed and dried to obtain the activated substrate.

The acid treatment can remove oxides and contaminants from the surface of the substrate and increase the content of polar functional groups. Subsequently, the pre-treated substrate is immersed in the ethanol solution of the coupling agent, such that the coupling agent is chemically bonded to the surface of the pre-treated substrate to enhance interfacial adhesion and improve wettability. It should be noted that immersing the pre-treated substrate in the ethanol solution of the coupling agent facilitates the binding of the coupling agent to the surface of the pre-treated substrate and also allows for easier cleaning.

In some embodiments, the substrate is an organic substrate. Before immersed in the ethanol solution of the coupling agent, the pre-treated substrate is subjected to plasma treatment. The plasma-treated organic substrate exhibits enhanced binding with the coupling agent. In some embodiments, argon or nitrogen may be used as the plasma gas, and the plasma treatment is performed for 30-300 s.

The method of the present disclosure is applicable to substrates of various materials. In some embodiments, the substrate is a glass substrate, a ceramic substrate, an organic substrate or a metal substrate. The coupling agent is a silane coupling agent or a titanate coupling agent.

The silane coupling agent reacts with hydroxyl groups (—OH) on the surface of the substrate through its siloxane group (Si—O—R) to form a chemical bond, while the other functional group (e.g., amino group, epoxy group) interacts as required. In some embodiments, the silane coupling agent is 3-aminopropyltriethoxysilane (KH-550) or 3-glycidoxypropyl) trimethoxysilane (KH-560).

A surface of the glass substrate contains a silanol group (Si—OH). The silane coupling agent is bonded to the glass substrate through hydrolysis and condensation reactions to form strong siloxane bonds (Si—O—Si). The processes of the hydrolysis and condensation reactions are as follows:

$$Hydrolysis reaction : R - {Si ( OR )}_{3} + {H}_{2} O \to R - {Si ( OH )}_{3} + ROH ; and$$

$$Condensation reatction : R - {Si ( OH )}_{3} + Si - OH \to R - Si - O - Si + {H}_{2} O .$$

After plasma treatment, polar functional groups (e.g., —COOH and —OH) are introduced onto the surface of the organic substrate. The epoxy groups of the silane coupling agent undergo ring-opening reactions with these polar groups to form covalent bonds. The process is as follows:

$$Epoxy ring - opening reaction : R - Si - OH + COOH \to R - Si - O - C = O - R .$$

A surface of the metal substrate contains an oxide layer (M-OH). The silane coupling agent undergoes condensation reactions to form metal-siloxane bonds. The process is as follows:

$$Metal bonding reaction : R - {Si ( OH )}_{3} + M - OH \to R - Si - O - M + {H}_{2} O .$$

After the pasty nano-filler is applied onto the substrate surface, the amino groups (—NH₂) or epoxy groups (—CH—O—CH₂) of the silane coupling agent are bound to surfaces of metal particles via electrostatic interactions or covalent bonds, thereby improving wettability and dispersibility. In some embodiments, when the pasty nano-filler is the nano-copper paste, the amino groups are bound to the copper surface as follows:

$$R - {NH}_{2} + CuO \to R - NH - Cu .$$

Titanate coupling agents (e.g., isopropyl tri (dioctyl pyrophosphate) titanate (NDZ-201)) contain titanium-oxygen bonds (Ti—O—R) and can react with hydroxyl groups or oxide layers on the substrate surface to form stable chemical bonds. A surface of the ceramic substrate contains metal oxides (e.g., Al—OH and Si—OH). The titanate coupling agent is bound to the ceramic substrate surface via coordination interactions to form strong bonds. The titanium atoms of the titanate coupling agent can form coordination bonds with oxygen atoms in the oxide layers on the surfaces of metal particles, thereby improving the adhesion and dispersibility of the filler. When the pasty nano-filler is the nano-copper paste, the coordination reaction is as follows:

$$Ti - O - R + Al - OH \to Ti - O - Al + R - OH ; and$$

$$Ti - O - R + Cu - OH \to Ti - O - Cu + R - OH .$$

In some embodiments, in step (2), the pasty nano-filler is applied onto the surface of the activated substrate by blade coating to reach a thickness of 10-30 μm, and the nano-filler-coated substrate is left to stand at room temperature, during which the microvias are self-filled with the pasty nano-filler through the capillary action. After the pasty nano-filler has completely filled the microvias upon standing, any excess pasty nano-filler on the nano-filler-coated substrate surface is gently removed using a doctor blade or a coater. In the present disclosure, microvia filling can be completed simply by allowing the coated pasty nano-filler to stand, thereby ensuring a simple and reliable operation.

In some embodiments, in step (3), the sintering treatment is performed through the following steps. The nano-filler-coated substrate is heated to 200-400° C. in a protective atmosphere at a rate of 10-20° C./min, and sintered at 200-400° C. for 5-30 min, and cooled to room temperature at a rate of 5-10° C./min.

It can be understood that different diameters of the microvias require different sintering temperatures to ensure complete curing of the pasty nano-filler. In some embodiments, when the diameter of each of the microvias is 1-10 μm, the sintering temperature is 200-250° C.; when the diameter of each of the microvias is 10-50 μm, the sintering temperature is 250-350° C.; and when the diameter of each of the microvias is 50-100 μm, the sintering temperature is 350-400° C.

The following embodiments are provided to further illustrate the present disclosure.

### Example 1

In this embodiment, microvias having a diameter of 5 μm and an aspect ratio of 100:1 in a glass substrate were filled through the following steps.

(1) The glass substrate was immersed in a 1 wt. % hydrofluoric acid solution for 5 min, rinsed thoroughly with ultrapure water, and then dried at 70° C. for 20 min. Then, the glass substrate was immersed in a 0.3 wt. % ethanol solution of KH-550 for 40 min, rinsed twice with anhydrous ethanol, and dried at 60° C. for 10 min.

(2) A nano-copper paste raw material was added with diethylamine and homogenized under vacuum stirring to obtain a nano-copper paste with a wetting angle of 10°, a viscosity of 1 Pa·s, and a copper particle size of 10-20 nm. The nano-copper paste was applied to a surface of the glass substrate by blade coating to reach a thickness of 10-30 μm, and then the substrate was left to stand at room temperature for 30 min, such that the nano-copper paste was driven by capillary action to enter into the microvias.

(3) The coated glass substrate was heated at a rate of 15° C./min to 300° C. in a nitrogen atmosphere, maintained at 300° C. for 15 min for sintering, and cooled to room temperature at a rate of 5° C./min, so as to form a high-density conductive copper structure in the glass substrate.

### Example 2

In this embodiment, microvias having a diameter of 30 μm and an aspect ratio of 80:1 in a ceramic substrate were filled through the following steps.

(1) The ceramic substrate was immersed in a 3 wt. % nitric acid solution for 8 min, rinsed thoroughly with ultrapure water, and then dried at 90° C. for 20 min. Then, the ceramic substrate was immersed in a 0.5 wt. % ethanol solution of NDZ-201 for 35 min, rinsed twice with anhydrous ethanol, and dried at 100° C. for 8 min.

(2) A nano-copper paste raw material was added with diethylene glycol monomethyl ether and homogenized under vacuum stirring to obtain a nano-copper paste with a wetting angle of 20°, a viscosity of 10 Pa·s, and a copper particle size of 20-50 nm. The nano-copper paste was applied to a surface of the ceramic substrate by blade coating to reach a thickness of 10-30 μm, and then the substrate was left to stand at room temperature for 30 min, such that the nano-copper paste was driven by capillary action to enter into the microvias.

(3) The coated ceramic substrate was heated at a rate of 15° C./min to 300° C. in a nitrogen atmosphere, maintained at 300° C. for 15 min for sintering, and cooled to room temperature at a rate of 5° C./min, so as to form a high-density conductive copper structure in the ceramic substrate.

### Example 3

In this embodiment, microvias having a diameter of 70 μm and an aspect ratio of 100:1 in an organic substrate were filled through the following steps.

(1) The organic substrate was immersed in a 2 wt. % acetic acid solution for 4 min, rinsed thoroughly with ultrapure water, and dried at 50° C. for 12 min. The organic substrate was subjected to plasma treatment using argon as the gas source for 200 s. Subsequently, the organic substrate was immersed in a 0.4 wt. % ethanol solution of KH-560 for 30 min, rinsed twice with anhydrous ethanol, and dried at 60° C. for 12 min.

(2) A nano-copper paste raw material was added with acetic acid and homogenized under vacuum stirring to obtain a nano-copper paste with a wetting angle of 15°, a viscosity of 8 Pa·s, and a copper particle size of 20-50 nm. The nano-copper paste was applied to a surface of the organic substrate by blade coating to reach a thickness of 10-30 μm, and then the substrate was left to stand at room temperature for 30 min, such that the nano-copper paste was driven by capillary action to enter into the microvias.

(3) The coated organic substrate was heated at a rate of 15° C./min to 300° C. in a nitrogen atmosphere, maintained at 300° C. for 15 min for sintering, and cooled to room temperature at a rate of 5° C./min, so as to form a high-density conductive copper structure in the organic substrate.

### Example 4

In this embodiment, microvias having a diameter of 100 μm and an aspect ratio of 500:1 in a metal substrate were filled through the following steps.

(1) The metal substrate was immersed in a 5 wt. % hydrochloric acid solution for 6 min, rinsed with anhydrous ethanol, and air-dried at room temperature for 15 min. The metal substrate was immersed in a 1 wt. % ethanol solution of KH-550 for 50 min, rinsed twice with anhydrous ethanol, and dried at 60° C. for 20 min.

(2) A nano-copper paste raw material was added with citric acid and homogenized under vacuum stirring to obtain a nano-copper paste with a wetting angle of 30°, a viscosity of 4 Pa·s, and a copper particle size of 60-100 nm. The nano-copper paste was applied to a surface of the metal substrate by blade coating to reach a thickness of 10-30 μm, and then the substrate was left to stand at room temperature for 30 min, such that the nano-copper paste was driven by capillary action to enter into the microvias.

(3) The coated metal substrate was heated at a rate of 15° C./min to 300° C. in a nitrogen atmosphere, maintained at 300° C. for 15 min for sintering, and cooled to room temperature at a rate of 5° C./min, so as to form a high-density conductive copper structure in the metal substrate.

### Example 5

In this embodiment, microvias having a diameter of 1 μm and an aspect ratio of 20:1 in a ceramic substrate were filled through the following steps.

(1) The ceramic substrate was immersed in a 3 wt. % nitric acid solution for 8 min, rinsed with ultrapure water, and dried at 90° C. for 20 min. Subsequently, the ceramic substrate was immersed in a 0.5 wt. % NDZ-201 ethanol solution for 35 min, rinsed twice with anhydrous ethanol, and dried at 100° C. for 8 min.

(2) A nano-copper paste raw material was added with diethylene glycol monomethyl ether and homogenized under vacuum stirring to yield a nano-copper paste with a wetting angle of 5°, a viscosity of 3 Pa·s, and a copper particle size of 20-50 nm. The nano-copper paste was applied to a surface of the ceramic substrate by blade coating to reach a thickness of 10-30 μm, and then the substrate was left to stand at room temperature for 30 min, such that the nano-copper paste was driven by capillary action to enter into the microvias.

(3) The coated ceramic substrate was heated at a rate of 15° C./min to 300° C. in a nitrogen atmosphere, maintained at 300° C. for 15 min for sintering, and cooled to room temperature at a rate of 5° C./min, so as to form a high-density conductive copper structure in the ceramic substrate.

The substrates obtained in Examples 1-5 were all found to exhibit high-density conductive copper structures, and the interlayer circuits demonstrated excellent connectivity.

Other configurations and operations of the method provided herein are known to those skilled in the art and are not described in detail herein.

As used herein, the terms “embodiment” and “example” are intended to indicate that the specific features, structures, materials, or characteristics described in connection with such an embodiment or example are included in at least one embodiment or example of the present disclosure. As used herein, such terms are used for illustrative purposes and do not necessarily refer to the same embodiment or example. Moreover, the described specific features, structures, materials, or characteristics may be suitably combined in any one or more embodiments or examples.

The embodiments described above are merely illustrative, and are not intended to limit the scope of the present disclosure. It should be understood that various modifications, changes and replacements made by those skilled in the art without departing from the spirit of the disclosure shall fall within the scope of the present disclosure defined by the appended claims.

What is claimed is:

1. A self-filling method for high-aspect-ratio microvias of a substrate, comprising:
(1) activating the substrate with a coupling agent to obtain an activated substrate;
(2) applying a pasty nano-filler on a surface of the activated substrate; wherein microvias in the activated substrate are self-filled with the pasty nano-filler through capillary action, the pasty nano-filler has a wetting angle of α≤30°, and each of the microvias has an aspect ratio of 5-500:1 and a diameter of 1-100 μm; and
(3) subjecting a nano-filler-coated substrate obtained in step (2) to sintering treatment.

2. The self-filling method according to claim 1, wherein when the diameter of each of the microvias is 1-10 μm, the wetting angle of the pasty nano-filler is α≤15°;
when the diameter of each of the microvias is 10-50 μm, the wetting angle of the pasty nano-filler is α≤20°; and
when the diameter of each of the microvias is 50-100 μm, the wetting angle of the pasty nano-filler is α≤30°.

3. The self-filling method according to claim 1, wherein the pasty nano-filler comprises an interfacial modifier; and the interfacial modifier is selected from the group consisting of an amine compound, a C₁-C₆ alcohol, a C₂-C₆ ether and an organic acid.

4. The self-filling method according to claim 3, wherein the interfacial modifier is selected from the group consisting of diethylamine, triethylamine, octylamine, ethanol, butanol, diethylene glycol monomethyl ether, formic acid, acetic acid and citric acid.

5. The self-filling method according to claim 3, wherein the pasty nano-filler has a viscosity of 1-10 Pa·s; and the pasty nano-filler further comprises metal particles having a particle size of 10-100 nm.

6. The self-filling method according to claim 1, wherein step (1) comprises:
immersing the substrate in an acid solution followed by washing and drying to obtain a pre-treated substrate; and
immersing the pre-treated substrate in an ethanol solution of the coupling agent followed by washing and drying to obtain the activated substrate.

7. The self-filling method according to claim 6, wherein the substrate is an organic substrate; and
before immersed in the ethanol solution of the coupling agent, the pre-treated substrate is subjected to plasma treatment.

8. The self-filling method according to claim 6, wherein the substrate is a glass substrate, a ceramic substrate, an organic substrate or a metal substrate; and the coupling agent is a silane coupling agent or a titanate coupling agent.

9. The self-filling method according to claim 1, wherein in step (2), the pasty nano-filler is applied onto the surface of the activated substrate by blade coating to reach a thickness of 10-30 μm, and the nano-filler-coated substrate is left to stand at room temperature, during which the microvias are self-filled with the pasty nano-filler through the capillary action.

10. The self-filling method according to claim 1, wherein in step (3), the sintering treatment is performed through steps of:
heating the nano-filler-coated substrate to 200-400° C. in a protective atmosphere at a rate of 10-20° C./min, and sintering the nano-filler-coated substrate at 200-400° C. for 5-30 min followed by cooling to room temperature at a rate of 5-10° C./min.
